(19) United States
(12) Patent Application Publication
(10) Pub. No.: US 2014/0268551 A1
(43) Pub. Date: Sep. 18, 2014

(54) ENCLOSURE HIGH PRESSURE PUSH-PULL AIRFLOW

(71) Applicant: Silicon Graphics International Corp., Fremont, CA (US)

(72) Inventors: Kevin Lee Van Pelt, Longmont, CO (US); Robert Michael Kinstle, III, Livermore, CA (US)

(73) Assignee: Silicon Graphics International Corp., Fremont, CA (US)

(21) Appl. No.: 14/038,588

(22) Filed: Sep. 26, 2013

Related U.S. Application Data
(60) Provisional application No. 61/786,409, filed on Mar. 15, 2013.

(51) Int. Cl. H05K 7/20

(52) U.S. Cl. CPC H05K 7/20718
USPC 361/679.48

(57) ABSTRACT

High pressure fans are mounted in the middle of an enclosure to create a low pressure zone and a high pressure zone within the enclosure. The high pressure fans pull air through high density sets of hard disk drives in the back of an enclosure and push air through high density disk drives in the front of the enclosure. Being positioned in the middle of an enclosure allows the high pressure fans to mix hot air pulled through the low pressure zone with cool air existing on the other side of the fans. The fans then push the cool mixed air through the next set of hard drives, forming a high pressure zone and allowing the air to exit at the front of the enclosure.

### CROSS REFERENCE TO RELATED APPLICATIONS

This application claims the priority benefit of U.S. Provisional Application Ser. No. 61/786,409, titled “Enclosure High Pressure Push-Pull Airflow,” filed Mar. 14, 2013, the disclosure of which is incorporated herein by reference.

### BACKGROUND OF THE INVENTION

1. Field of the Invention

The present invention relates to enclosure cooling systems. In particular, the present invention relates to high pressure cooling fans providing cooling in an enclosure.

2. Description of the Related Art

Data centers provide storage enclosures within racks and mass numbers of racks to provide storage to their customers. As the need for data and storage space increases, the enclosures must provide more data storage space while still operating reliably.

Within storage enclosures, airflow paths are commonly configured to cool down components within the enclosure. For example, FIG. 1 illustrates a data storage enclosure of the prior art. The enclosure 110 of FIG. 1 includes hard disk drives 130 and 132, printed circuit boards 140, 142 and 144, entry air vents 120 and 122, exit air vents 160 and 162, and low pressure fans 150 and 152. The enclosure of the prior art provides for generous spacing between elements and positioning of elements to create airflow channels.

For example, hard disk drives 130 and 132 are positioned towards the front of the enclosure and have significant spacing between them. The hard disk drives of prior art enclosures are typically separated by at least a quarter of an inch. Additionally, there are usually only one or two rows of hard disk drives within prior art data storage system enclosures towards one end of the disclosure. Printed circuit boards are typically installed within an enclosure so as to create rails or guides for airflow to travel from the front of an enclosure towards the rear of the enclosure. As illustrated, printed circuit boards 140, 142 and 144 creates airflow channels 170 and 172 within the enclosure. In fact, the entire enclosure is designed such that airflow channels 170 and 172 may flow from the rear enclosure vents 120 and 122 through front enclosure exit vents 160 and 162. To provide the airflows, fans 150 and 152 are positioned directly in front of front vents 160 and 162, also within the line of airflow channels 170 and 172.

The low pressure fans are provided in the front of the enclosure and directly in front of the airflow channels and provide a very low pressure to pull air through the entire enclosure. These low pressure fans located at one side of an enclosure provide adequate cooling for enclosures with low numbers of hard disk drives which include generous spacing between them and clear airflow channels. These lower pressure fans, however, are not adequate for enclosures that might include additional hard disk drives and blockage to traditional airflow channels within an enclosure.

What is needed is an improved system for cooling enclosures having more densely packed hard disk drives and less air channel friendly layouts.

### SUMMARY OF THE CLAIMED INVENTION

The present invention includes high pressure fans that are mounted in the middle of an enclosure to create a low pressure zone and a high pressure zone within the enclosure. The high pressure fans pull air through high density sets of hard disk drives in the back of an enclosure and push air through high density disk drives in the front of the enclosure. Being positioned in the middle of an enclosure allows the high pressure fans to mix hot air pulled through the low pressure zone with cool air existing on the other side of the fans. The fans then push the cool mixed air through the next set of hard drives, forming a high pressure zone, and allowing the air to exit at the front of the enclosure.

An embodiment includes an enclosure for a data storage system. The data enclosure includes a chassis, first set of storage devices, second set of storage devices, a base, a first end and a second end, and a set of one or more fans. The first set of storage devices may be disposed in the enclosure near the chassis first end. The second set of storage devices may be disposed in the enclosure near the chassis second end. The set of one or more fans may be disposed near a center of the chassis and within the enclosure, and positioned between the first set of storage devices and the second set of storage devices.

### BRIEF DESCRIPTION OF THE DRAWINGS

FIG. 1 includes a data storage enclosure of the prior art.

FIG. 2 is a top view of a data storage enclosure of the present invention.

FIG. 3A is perspective view of a data storage enclosure of the present invention.

FIG. 3B is perspective view of an exploded data storage enclosure of the present invention.

FIG. 3C illustrates a method for cooling a data storage enclosure having a high density of components.

FIG. 4 illustrates a temperature change versus distance chart along a prior art data storage enclosure.

FIG. 5 illustrates a temperature change versus distance chart along a data storage enclosure of the present invention.

### DETAILED DESCRIPTION

In embodiments, high pressure fans are mounted in the middle of an enclosure to create a low pressure zone and a high pressure zone within the enclosure. The high pressure fans pull air through high density sets of storage devices, like hard disk drives, in the front of an enclosure and push air through high density disk drives in the back of the enclosure. Being positioned in the middle of an enclosure allows the high pressure fans to mix hot air pulled through the low pressure zone with cool air bypassing the front drives. The fans then push the cool mixed air through the next set of hard drives, forming a high pressure zone and allowing the air to exit at the back of the enclosure.

FIG. 2 provides a top view of a data storage enclosure of the present invention. The enclosure of FIG. 2 includes a first set of hard disk drives consisting of disk drives 220, 222, and 224, a chassis 210, entry vent 215, high pressure fans 230 and 232, condensed printed circuit board circuitry 250, a second set of hard drives consisting of hard drive rows 240, 242 and 244, and one or more exit vents 280. Chassis 210 may include sides, a base, and a top portion to create the frame of the enclosure. In some instances, an enclosure may include 1-2 server modules in communication with the first set of storage devices and the second set of storage devices.

The first set of hard disk drives may include hard disk drive rows 220, 222, and 224. The disk drives are highly condensed within the first set of disk drives. The separation between disk drives within the first set of disk drives may be less than ⅛ of an inch. For example, the typical separation between disk drives within the first set of disk drives may be 1/16^{th} of an inch.

The second set of disk drives consists of disk drive rows 240, 242, and 244. The second set of disk drives is also very high density, and typically includes a separation between disk drives of less than ⅛ of an inch, for example 1/16^{th} of an inch. Between the first set of disk drives and second set of disk drives are high pressure fans. High pressure fans 230 and 232 may be dual impeller, counter rotary (the impellers rotate in opposite directions), and produce a static pressure greater than or equal to three inches of water. Such high pressure fans are typically not used within enclosures because they are louder than usual and create undesirable noise. However, when placed in the middle of an enclosure, the noise is dampened out by the high density of disk drives in the first set of disk drives and second set of disk drives.

The high pressure fans 230 and 232 draw air from the front of the enclosure through one or more entry vents 215 and push air towards the back of the enclosure. As such, the fans create a low pressure zone 260 over the first set of hard disk drives and a high pressure zone 270 around the second set of disk drives. The high pressure fans ultimately drive air through the high pressure zone and out of the enclosure through one or more exit vents 280 and 282. These multiple pressure zones created within the enclosure help cool the enclosure during operation.

The enclosure of the present invention which includes the high pressure fans in the middle of the enclosure is different from the prior art enclosures in several ways. Because the disk drives and condensed printed circuit board circuitry are denser than that of the prior art, very limited airflow channels exist within the enclosure. Air is forced through multiple pressure zones within the enclosure. The multiple pressure zone pressures help direct air between the narrow separation between the disk drives and high density printed circuit board circuitry. This makes the cooling much less directional or dependent on large openings and direct, clear paths into and out of the fans. A blockage between the fan and device to be cooled has little consequence if it is in the high or low pressure areas as long as there is a path the air can take around it.

FIG. 3A is a perspective view of a data storage enclosure of the present invention. The enclosure of FIG. 3A includes base 310(shown transparent), sides 312, fans 320 and 322, hard disk drive rows 330, 332 and 334 for a first set of hard disk drives, and hard disk drive rows 340 and 342 for a second set of disk drives. The enclosure of FIG. 3A shows the frame of the enclosure—the enclosure is not filled with disk drives. As illustrated, there is very little space between the disk drives which implement the first set of disk drives and second set of disk drives. There are minor and small slots associated within sub-portions of the framing where the rows of hard drives are positioned within the enclosure of FIG. 3A. The slots allow air to travel through the high density sections of hard disk drives.

FIG. 3B is perspective view of an exploded data storage enclosure of the present invention. Enclosure 370 of FIG. 3B includes hard disk drive rows 350, 352, 254, 358, 360, and 362. The exploded data storage enclosure 370 illustrates various components extending out of the enclosure (i.e., exploded view), including fan 356. Fan 356 is one of several fans that may be disposed within the enclosure between HDD rows 358 and 354.

FIG. 3C illustrates a method for cooling a data storage enclosure having a high density of components. The method of FIG. 3A may be performed for the data storage enclosure of FIGS. 2-3. The method of FIG. 3 begins with initializing the data storage enclosure. Initializing the data storage enclosure may include providing power to the enclosure, executing a start-up routine, and other initialization functions.

Power may be provided to one or more high pressure fans within the data storage enclosure at step 360. Each of one or more high pressure fans may have a dual impeller and counter rotary operation. Each of the one or more high pressure fans may be positioned or disposed within the data storage enclosure in such a position so as to provide a low pressure zone and a high pressure zone when the fans are powered on. Each fan may create a low pressure zone by withdrawing air away from a portion of the data storage enclosure. For example, fans 230 and 232 of the enclosure in FIG. 2 may withdraw air through entry vents 215, creating a low pressure zone between the entry vents and the fans. Similarly, each fan may create a high pressure zone by forcing air into a portion of the data storage enclosure. Fans 230 and 232 drive air through exit vent 280, creating a high pressure zone between the fans the exit vent. The low pressure zone and high pressure zone created in the data storage enclosure at step 370 contribute to overall airflow through the data storage enclosure having a high density of storage drives and other components. The multi-pressure zone created by the high pressure fans keep the data storage enclosure at cooler temperatures that what would be achieved with typical low pressure fans positioned near a vent.

FIG. 4 illustrates a temperature change versus distance graph along a prior art data storage enclosure. As shown, at the front of a prior art enclosure, the temperature is relatively low. Towards the back of the enclosure, however, the temperature increases. Hence, even with a low density disk drive layout and air channels created with vents, fans, and printed circuit boards, the temperature steadily increases along an enclosure of the prior art.

FIG. 5 illustrates temperature change versus distance graph along a data storage enclosure of the present invention. As shown, at the very front of the enclosure, the temperature is relatively low. Traversing from the front of the enclosure towards the middle, the temperature increases during a low pressure zone 510. Near the middle of the enclosure space, the temperature drops. The temperature drop is due to air mix by the high pressure fans between the preheated air from the front drive sets and the cooler, bypass air from outside the enclosure, which reduces the temperature in the mixed air. High pressure zone 520 also experiences a temperature increase, but benefits from the temperature drop due to the air mixture implemented near the middle of the enclosure by the fans.

The foregoing detailed description of the technology herein has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

What is claimed is:

1. An enclosure for a data processing system, comprising:
a chassis having a base, a first end and a second end;
a first set of storage devices disposed in the enclosure near the chassis first end;
a second set of storage devices disposed in the enclosure near the chassis second end;
a set of one or more fans disposed near a center of the chassis and within the enclosure, the set of one or more fans disposed between the first set of storage devices and the second set of storage devices.

2. The enclosure of claim 1, wherein the set of fans creating a low pressure zone near the first set of storage devices and a high pressure zone near the second set of storage devices.

3. The enclosure of claim 1, wherein the fans produce a static pressure of at least two inches of water.

4. The enclosure of claim 1, wherein the fans operate at greater than 10,000 rotations per minute.

5. The enclosure of claim 1, wherein the storage devices in the first set of storage devices are positioned in rows and columns in a horizontal plane that is about parallel to the chases base, the storage devices in the first set having a spacing of about one-sixteenth to one-eighth of an inch between them.

6. The enclosure of claim 5, wherein the storage devices in the second set of storage devices are positioned in rows and columns in the horizontal plane, the storage devices in the second set having a spacing of about one-sixteenth to one-eighth of an inch between them.

7. The enclosure of claim 1, wherein the enclosure includes 1-2 server modules in communication with the first set of storage devices and the second set of storage devices.

8. A method for cooling an enclosure, comprising:
providing power to one or more fans within an enclosure, each of the one or more fans disposed within the enclosure so as to leave a first space between an entry vent and the one or more fans and a second space between an exit vent and the one or more fans;
creating a low pressure zone between the one or more fans and the entry vent; and
creating a high pressure zone between the one or more fans and the exit vent.

9. The method of claim 8, wherein the low pressure zone and the high pressure zone are provided by one or more fans having dual impellers.

10. The method of claim 9, wherein the low pressure zone and the high pressure zone are provided by one or more fans impellers that rotate in counter directions.

11. The method of claim 8, wherein the low pressure zone includes a plurality of disk drives separated by less than one eighth of an inch.

12. The method of claim 8, wherein the high pressure zone includes a plurality of disk drives separated by less than one eighth of an inch.
